(19) United States
(12) Patent Application Publication
(10) Pub. No.: US 2026/0052951 A1
(43) Pub. Date: Feb. 19, 2026

(54) FILM FRAME CARRIER WITH WHOLE WAFER HYBRID CHUCK

(71) Applicant: KLA Corporation, Milpitas, CA (US)

(72) Inventors: Chow Tian Lim, Singapore (SG); Rajeev Patil, Fremont, CA (US)

(21) Appl. No.: 18/978,568

(22) Filed: Dec. 12, 2024

Related U.S. Application Data
(60) Provisional application No. 63/682,341, filed on Aug. 13, 2024.

(51) Int. Cl. H01L 21/683; G05B 19/04

(52) U.S. Cl. CPC H01L 21/6838; G05B 19/041; G05B 2219/2602

(57) ABSTRACT

The system includes a chuck defining a planar surface and peripheral surface surrounding the planar surface, a plurality of lift pins disposed within a plurality of apertures defined in the planar surface of the chuck, and a plurality of frame handles connected to the peripheral surface of the chuck. The plurality of lift pins are configured to extend out of the plurality of apertures above the planar surface to support a whole wafer, and the plurality of frame handles are configured to support a frame of a film frame carrier. The plurality of lift pins are further configured to retract into the plurality of apertures beneath the planar surface, with the planar surface of the chuck being configured to support a wafer of the film frame carrier.

### CROSS-REFERENCE TO RELATED APPLICATIONS

This application claims priority to the provisional patent application filed Aug. 13, 2024, and assigned U.S. App. No. 63/682,341, the disclosure of which is hereby incorporated by reference.

### FIELD OF THE DISCLOSURE

This disclosure relates to semiconductor fabrication and inspection and, more particularly, to a chuck configured to support a semiconductor wafer during fabrication and inspection.

### BACKGROUND OF THE DISCLOSURE

Evolution of the semiconductor manufacturing industry is placing greater demands on yield management and, in particular, on metrology and inspection systems. Critical dimensions continue to shrink, yet the industry needs to decrease time for achieving high-yield, high-value production. Minimizing the total time from detecting a yield problem to fixing it determines the return-on-investment for a semiconductor manufacturer.

Fabricating semiconductor devices, such as logic and memory devices, typically includes processing a semiconductor wafer using a large number of fabrication processes to form various features and multiple levels of the semiconductor devices. For example, lithography is a semiconductor fabrication process that involves transferring a pattern from a reticle to a photoresist arranged on a semiconductor wafer. Additional examples of semiconductor fabrication processes include, but are not limited to, chemical-mechanical polishing (CMP), etch, deposition, and ion implantation. An arrangement of multiple semiconductor devices fabricated on a single semiconductor wafer may be separated into individual semiconductor devices.

Inspection processes are used at various steps during semiconductor manufacturing to detect defects on wafers to promote higher yield in the manufacturing process and, thus, higher profits. Inspection has always been an important part of fabricating semiconductor devices such as integrated circuits (ICs). However, as the dimensions of semiconductor devices decrease, inspection becomes even more important to the successful manufacture of acceptable semiconductor devices because smaller defects can cause the devices to fail. For instance, as the dimensions of semiconductor devices decrease, detection of defects of decreasing size has become necessary because even relatively small defects may cause unwanted aberrations in the semiconductor devices.

Some semiconductor devices are fabricated on whole wafers that are thick enough to be independently handled by wafer handling equipment between fabrication and inspection steps. Other semiconductor devices are fabricated on thin wafers carried by a film frame carrier (FFC) between fabrication and inspection steps. The FFC consists of a frame that holds the wafer, which provides protection during transport. Due to the additional structure of the frame of the FFC and the fragility of the thin wafer, different types of chucks are used to support whole wafers and FFCs during fabrication and inspection processes. In order to process different whole wafers and FFCs, the chuck would need to be replaced, which results in tool downtime and reduces throughput. Alternatively, redundant fabrication and inspection stations would need to be included in the system for handling each type of wafer, which significantly increases hardware costs.

Therefore, what is needed is an improved chuck for supporting different types of wafers in the fabrication and inspection processes.

### BRIEF SUMMARY OF THE DISCLOSURE

An embodiment of the present disclosure provides a system. The system may comprise a chuck defining a planar surface and peripheral surface surrounding the planar surface. The system may further comprise a plurality of lift pins disposed within a plurality of apertures defined in the planar surface of the chuck. The plurality of lift pins may be configured to extend out of the plurality of apertures above the planar surface to support a whole wafer. The system may further comprise a plurality of frame handles connected to the peripheral surface of the chuck. The plurality of frame handles may be configured to support a frame of a film frame carrier. The plurality of lift pins may be further configured to retract into the plurality of apertures beneath the planar surface, and the planar surface of the chuck may be configured to support a wafer of the film frame carrier.

In some embodiments, a plurality of mounting ports may be further defined in the planar surface. The system may further comprise a plurality of orifice screws disposed in each of the plurality of mounting ports. The plurality of orifice screws may be configured to secure the chuck to a base member disposed beneath the chuck. The system may further comprise a plurality of seal plugs disposed in the plurality of mounting ports and flush with the planar surface. The wafer of the film frame carrier may be at least partially supported by the plurality of seal plugs on the planar surface of the chuck.

In some embodiments, each seal plug may include an access port that is coaxial with an axial bore of each orifice screw. The system may further comprise a plurality of set screws disposed in the access port of each of the plurality of seal plugs and extending to abut each orifice screw. The plurality of set screws may be configured to support the plurality of seal plugs to remain flush with the planar surface of the chuck.

In some embodiments, the system may further comprise a vacuum source. A plurality of vacuum ports may be further defined in the planar surface. The vacuum source may be in fluid communication with the plurality of vacuum ports, and the vacuum source may be configured to apply negative pressure to the wafer of the film frame carrier supported on the planar surface of the chuck through the plurality of vacuum ports.

In some embodiments, the plurality of vacuum ports may include a central hub defined by ports provided in a circular arrangement around a center point of the chuck and a plurality of micro ports distributed across the planar surface of the chuck surrounding the central hub.

In some embodiments, the plurality of lift pins may each comprise a pin body having an axial bore. The pin body may be configured to axially move within one of the plurality of apertures. The vacuum source may be in fluid communication with the axial bore, and the vacuum source may be configured to apply the negative pressure to the wafer supported on the planar surface of the chuck through the axial bore.

In some embodiments, the plurality of lift pins may each further comprise a pin cap disposed on the pin body. The pin cap may define a pin hole coaxial with the axial bore and in fluid communication with the vacuum source. The wafer of the film frame carrier may be at least partially supported by the pin cap on the planar surface of the chuck.

In some embodiments, the plurality of lift pins may each further comprise a wave spring configured to suspend the pin cap on the pin body as the whole wafer is supported by the plurality of lift pins above the planar surface of the chuck.

In some embodiments, the system may further comprise a processor. The processor may be configured to control the vacuum source to apply the negative pressure to the wafer of the film frame carrier supported on the planar surface of the chuck through the plurality of vacuum ports.

In some embodiments, the system may further comprise an actuator disposed beneath the chuck. The actuator may be configured to simultaneously lift the plurality of lift pins to extend out of the plurality of apertures above the planar surface of the chuck, and the actuator may be further configured to simultaneously lower the plurality of lift pins to retract into the plurality of apertures beneath the planar surface of the chuck.

In some embodiments, the processor may be configured to control the actuator to lift the plurality of lift pins to extend out of the plurality of apertures above the planar surface of the chuck and lower the plurality of lift pins to retract into the plurality of apertures beneath the planar surface of the chuck.

In some embodiments, the system may further comprise a first end effector configured to support the whole wafer and removably dispose the whole wafer onto the plurality of lift pins extended out of the plurality of apertures above the planar surface of the chuck. The system may further comprise a second end effector configured to support the film frame carrier and removably dispose the frame of the film frame carrier onto the plurality of frame handles and the wafer of the film frame carrier onto the planar surface of the chuck.

In some embodiments, the system may further comprise a robot arm. The robot arm may be configured to engage the first end effector and move the first end effector to removably dispose the whole wafer onto the plurality of lift pins extended out of the plurality of apertures above the planar surface of the chuck.

In some embodiments, the robot arm may be further configured to engage the second end effector and move the second end effector to removably dispose the frame of the film frame carrier onto the plurality of frame handles and the wafer of the film frame carrier onto the planar surface of the chuck.

Another embodiment of the preset disclosure provides a method. The method may comprise providing a chuck defining a planar surface and peripheral surface surrounding the planar surface. The method may further comprise controlling a plurality of lift pins disposed within a plurality of apertures defined in the planar surface of the chuck to extend out of the plurality of apertures above the planar surface of the chuck. The method may further comprise disposing a whole wafer on the plurality of lift pins extended out of the plurality of apertures above the planar surface of the chuck. The method may further comprise removing the whole wafer from the plurality of lift pins. The method may further comprise controlling the plurality of lift pins to retract into the plurality of apertures beneath the planar surface of the chuck. The method may further comprise disposing a frame of a film frame carrier onto a plurality of frame handles connected to the peripheral surface of the chuck, with a wafer of the film frame carrier being supported by the planar surface of the chuck. The method may further comprise removing the frame of the film frame carrier from the plurality of frame handles.

In some embodiments, the method may further comprise controlling a vacuum source to apply negative pressure to the wafer of the film frame carrier supported on the planar surface of the chuck through a plurality of vacuum ports defined in the planar surface of the chuck.

In some embodiments, disposing the whole wafer on the plurality of lift pins extended out of the plurality of apertures above the planar surface of the chuck may comprise moving a first end effector supporting the whole wafer in a direction normal to the planar surface of the chuck over the plurality of lift pins extended out of the plurality of apertures above the planar surface of the chuck; releasing the whole wafer from the first end effector to dispose the whole wafer onto the plurality of lift pins; and moving the first end effector away from the chuck in a direction parallel to the planar surface of the chuck.

In some embodiments, removing the whole wafer from the plurality of lift pins may comprise moving the first end effector in the direction parallel to the planar surface of the chuck between the planar surface and the whole wafer; engaging the whole wafer supported by the plurality of lift pins with the first end effector; and moving the first end effector away from the chuck in the direction normal to the planar surface of the chuck to remove the whole wafer from the plurality of lift pins.

In some embodiments, disposing the frame of the film frame carrier onto the plurality of frame handles may comprise moving a second end effector supporting the frame of the film frame carrier in a direction normal to the planar surface of the chuck over the plurality of frame handles; releasing the frame of the film frame carrier from the second end effector to dispose the frame of the film frame carrier onto the plurality of frame handles, with the wafer of the film frame carrier being supported by the planar surface of the chuck; and moving the second end effector away from the chuck in a direction parallel to the planar surface of the chuck.

In some embodiments, removing the frame of the film frame carrier from the plurality of frame handles may comprise moving the second end effector in the direction parallel to the planar surface of the chuck beneath the frame of the film frame carrier; engaging the frame of the film frame carrier supported by the plurality of frame handles with the second end effector; and moving the second end effector away from the chuck in the direction normal to the planar surface of the chuck to remove the frame of the film frame carrier from the plurality of frame handles.

### DESCRIPTION OF THE DRAWINGS

For a fuller understanding of the nature and objects of the disclosure, reference should be made to the following detailed description taken in conjunction with the accompanying drawings, in which:

FIG. 1A is a cross-sectional view of a system according to an embodiment of the present disclosure;

FIG. 1B is a top view of the system of FIG. 1A;

FIG. 2A is a cross-sectional view of the system of FIG. 1A supporting a whole wafer;

FIG. 2B is a top view of the system of FIG. 2A;

FIG. 3A is a cross-sectional view of the system of FIG. 1A supporting a film frame carrier;

FIG. 3B is a top view of the system of FIG. 3A;

FIG. 4A is a detail section view of a vacuum port of a system according to an embodiment of the present disclosure;

FIG. 4B is a detail section view of a vacuum port of a system according to another embodiment of the present disclosure;

FIG. 5A is a detail section view of a lift pin of a system according to an embodiment of the present disclosure in a retracted position;

FIG. 5B is a detail section view of the lift pin of FIG. 4A in an extended position;

FIG. 6 is a top view a system according to an embodiment of the present disclosure with a first end effector of a robot arm supporting a whole wafer;

FIG. 7 is a top view of a system according to an embodiment of the present disclosure with a second end effector of a robot arm supporting a film frame carrier;

FIG. 8 is a flowchart of a method according to an embodiment of the present disclosure;

FIG. 9 is a flowchart of a method according to another embodiment of the present disclosure;

FIG. 10 is a flowchart of a method according to another embodiment of the present disclosure;

FIG. 11 is a flowchart of a method according to another embodiment of the present disclosure; and

FIG. 12 is a flowchart of a method according to another embodiment of the present disclosure.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

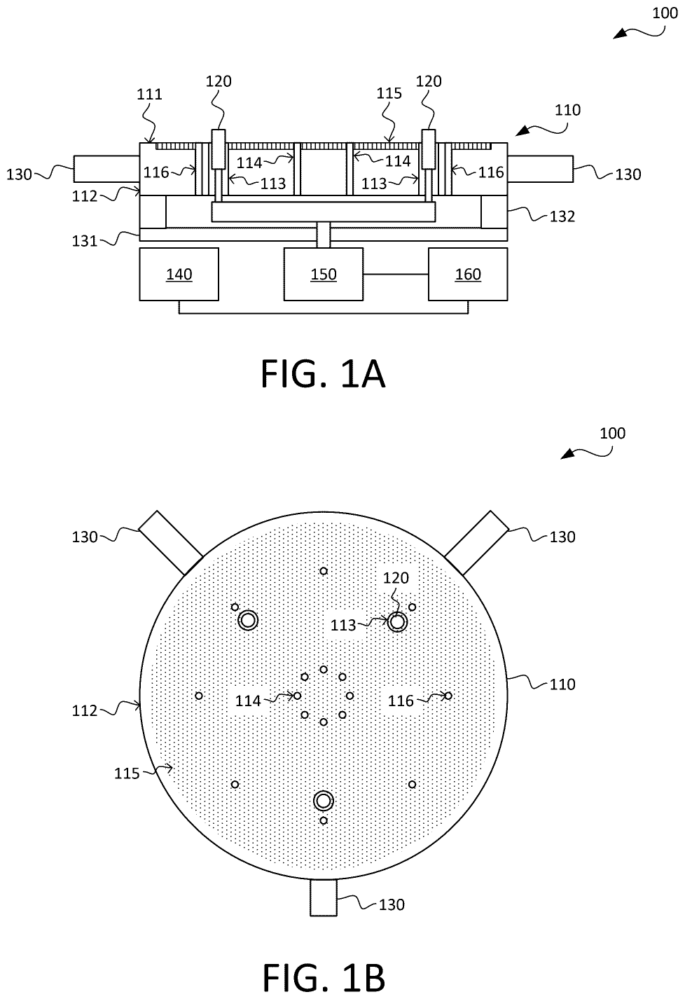

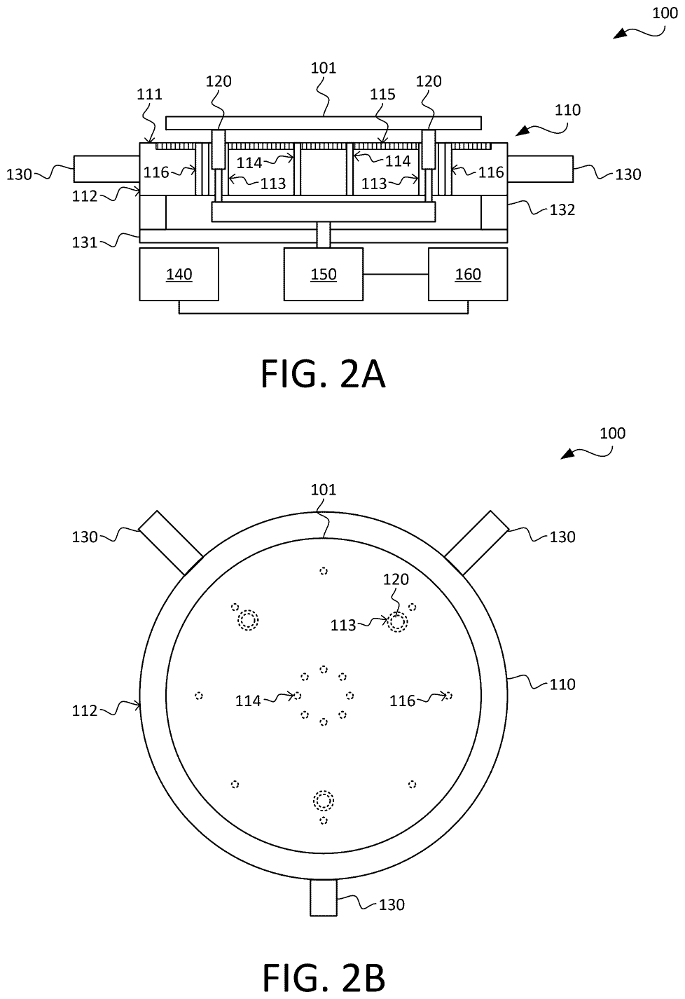

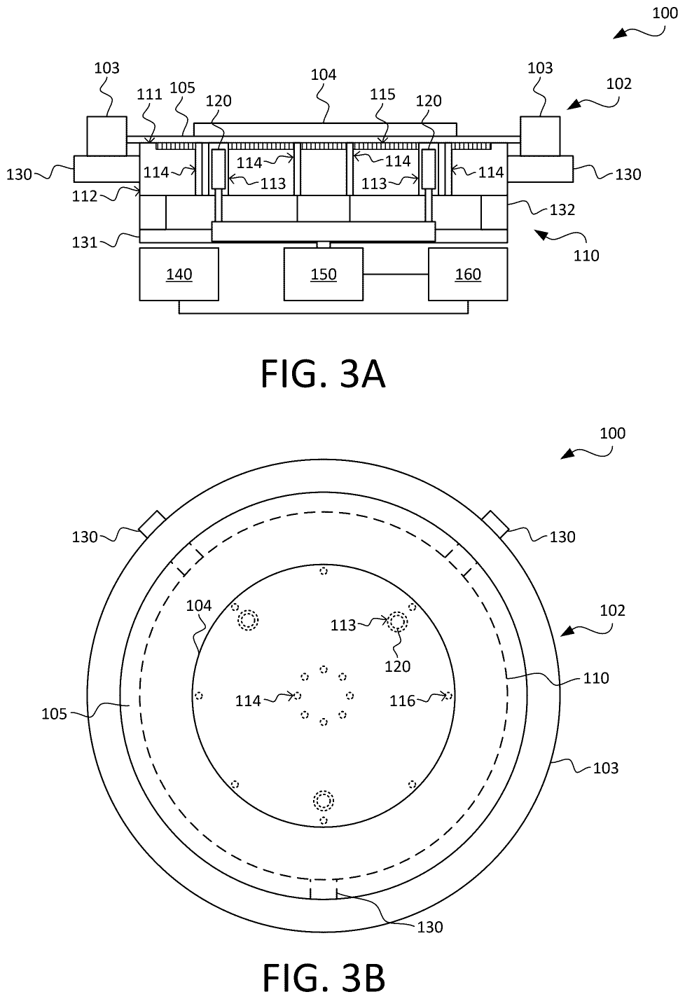

An embodiment of the present disclosure provides a system 100, shown in FIG. 1A and FIG. 1B. The system 100 may be configured to perform one or more fabrication or inspection processes on a semiconductor wafer. The semiconductor wafer may be a whole wafer 101 (as shown in FIG. 2A and FIG. 2B) or a film frame carrier 102 (as shown in FIG. 3A and FIG. 3B). The whole wafer 101 may be a circular wafer having a diameter of 150 mm to 450 mm. For example, the whole wafer 101 may have a diameter of 200 mm (referred to as an “8-inch wafer”) or 300 mm (referred to as a “12-inch wafer”). The film frame carrier 102 may comprise a frame 103 configured to support a wafer 104. The wafer 104 may be thinner than the whole wafer 101, and thus the frame 103 may be configured to protect and support the wafer 104 during fabrication and inspection, while the whole wafer 101 may be self-supporting. In some embodiments, the wafer 104 may be a wafer paste. The wafer 104 may be suspended by a film 105 supported by the frame 103. For example, a film 105 with a thickness of at least 60 μm may be configured to support a wafer 104 with a minimum thickness of 50 μm. The wafer 104 of the film frame carrier 102 may be a circular wafer having a diameter of 150 mm to 450 mm. For example, the wafer 104 of the film frame carrier 102 may have a diameter of 200 mm (referred to as an “8-inch wafer”) or 300 mm (referred to as a “12-inch wafer”). In some embodiments, the wafer 104 may be comprised of a plurality of dies stuck on the film 105 (referred to as a “recon wafer”) to form a circular wafer. The diameter of the frame 103 may be larger than the diameter of the wafer 104, with the frame 103 being configured to support wafers 104 of various diameters.

The system 100 may comprise a chuck 110 configured to support each of the whole wafer 101 and the film frame carrier 102. The chuck 110 may define a planar surface 111 and peripheral surface 112 surrounding the planar surface 111. In some embodiments, the chuck 110 may be cylindrical, with the planar surface 111 being a circular top surface of the chuck 110 and the peripheral surface 112 being an annular side surface of the chuck 110. The diameter of the planar surface 111 of the chuck 110 may be greater than or equal to the diameter of the whole wafer 101 or the wafer 104 of the film frame carrier 102. For example, a diameter of the planar surface 111 of the chuck 110 that is greater than 300 mm (e.g., 310 mm) may be configured to support a whole wafer 101 and a wafer 104 of a film frame carrier 102 that is 300 mm or less (i.e., both 300 mm wafers and 200 mm wafers) and to accommodate for separation between dies of a recon wafer.

The system 100 may further comprise a plurality of lift pins 120. The plurality of lift pins 120 may be disposed within a plurality of apertures 113 defined in the planar surface 111 of the chuck 110. The plurality of apertures 113 may be circumferentially arranged on the planar surface 111 of the chuck 110 in a regular arrangement or symmetrical pattern. The radial position of each of the plurality of apertures 113 relative to a center point of the planar surface 111 of the chuck 110 may be provided such that each of the plurality of apertures 113 may be covered by the whole wafer 101. For example, the plurality of apertures 113 may be arranged within a circular area having a diameter of 200 mm for the plurality of lift pins 120 to support a whole wafer 101 having a diameter of 200 mm. In the illustrated embodiment of FIG. 1B, the plurality of apertures 113 are defined in a triangular arrangement on the planar surface 111 of the chuck 110, such that each of the plurality of lift pins 120 are covered by the whole wafer 101 (as shown in FIG. 2B). The plurality of lift pins 120 may be configured to extend out of the plurality of apertures 113 above the planar surface 111 of the chuck 110 to support the whole wafer 101, as shown in FIG. 2A. For example, the plurality of lift pins 120 may extend out of the plurality of apertures 113 up to 18 mm above the planar surface 111 of the chuck 110. In some embodiments, a shorter extension (i.e., a “stroke”) of the plurality of lift pins 120 (e.g., 13 mm) may be used to reduce vibration, which could damage a thin die wafer 104 if vibration is too strong. The plurality of lift pins 120 may be further configured to retract into the plurality of apertures 113 beneath the planar surface 111 to support the wafer 104 of the film frame carrier 102, as shown in FIG. 3A.

The system 100 may further comprise a plurality of frame handles 130. The plurality of frame handles 130 may be connected to the peripheral surface 112 of the chuck 110. For example, the plurality of frame handles 130 may be arranged at regular intervals around the circumference of the chuck 110 or at symmetrical positions relative to the chuck 110. In the illustrated embodiment of FIG. 1B, the plurality of frame handles 130 are symmetrically arranged relative to a middle frame handle at the bottom of the figure. The plurality of frame handles 130 may be configured to support the frame 103 of the film frame carrier 102. For example, the plurality of frame handles 130 may extend radially outward from the peripheral surface 112 of the chuck 110 by a distance to support the frame 103 of the film frame carrier 102 (as shown in FIG. 3B).

The system 100 may further comprise a vacuum source 140. A plurality of vacuum ports may be further defined in the planar surface 111 of the chuck 110, as shown in FIG. 1B, including a central hub 114 and a plurality of micro ports 115 arranged on the planar surface 111 of the chuck 110 in a regular arrangement or a symmetrical pattern. For example, the central hub 114 may be defined by ports provided in a circular arrangement around the center point of the chuck 110, and the plurality of micro ports 115 may be distributed across the planar surface 111 of the chuck 110 surrounding the central hub 114. The radial position of the central hub 114 relative to the center point of the planar surface 111 of the chuck 110 may be provided such that the central hub 114 and at least some of the plurality of micro ports 115 may be covered by the wafer 104 of the film frame carrier 102. In some embodiments, the plurality of vacuum ports may include one or more circular arrangements on the planar surface 111 of the chuck 110, with each circular arrangement being provided at a different radial position relative to the center of the planar surface 111 of the chuck 110. The vacuum source 140 may be in fluid communication with the plurality of vacuum ports. For example, one or more vacuum lines or channels (not shown) may be provided in the chuck 110, connected to each of the ports of the central hub 114 and the plurality of micro ports 115 and to the vacuum source 140. The vacuum source 140 may be configured to apply negative pressure to the wafer 104 of the film frame carrier 102 supported on the planar surface 111 of the chuck 110 through the plurality of vacuum ports. Accordingly, the wafer 104 of the film frame carrier 102 may be held in position by the chuck 110 when one or more fabrication or inspection processes are performed on the wafer 104.

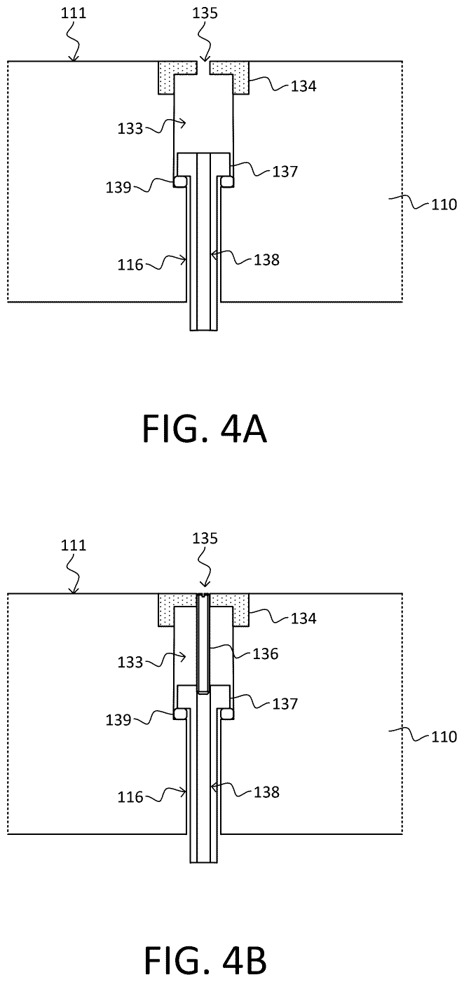

A plurality of mounting ports 116 may further be defined in the planar surface 111 of the chuck 110. The plurality of mounting ports 116 may be configured to receive a plurality of orifice screws 137, as shown in FIG. 4A and FIG. 4B. The plurality of orifice screws 137 may be configured to secure the chuck 110 to a rigid body (e.g., base member 131). The plurality of mounting ports 116 may therefore provide access to the plurality of orifice screws 137 for securing and removing the chuck 110 from the rigid body. The plurality of orifice screws 137 may have an axial bore 138. A sealing member 139 may be provided to seal each of the plurality of orifice screws 137 in the plurality of mounting ports 116. The axial bore 138 of the orifice screw 137 may be connected to atmospheric pressure. Accordingly, a reservoir 133 formed between each orifice screw 137 and the planar surface 111 of the chuck 110 may be re-filled with atmospheric pressure (not vacuum pressure) as the vacuum source 140 applies negative pressure to the wafer 104 of the film frame carrier 102 supported on the planar surface 111 of the chuck 110 through the plurality of vacuum ports.

The system 100 may further comprise a plurality of seal plugs 134 disposed in the plurality of mounting ports 116 and flush with the planar surface 111 of the chuck 110, as shown in FIG. 4A and FIG. 4B. The plurality of seal plugs 134 may each include an access port 135 for removal of each seal plug 134 (e.g., by insertion of an extraction tool) to access each orifice screw 137 for securing and removing the chuck 110 from the rigid body. The access port 135 may be coaxial with the axial bore 138 of the orifice screw 137. The plurality of seal plugs 134 may be made of an elastomeric material and press fit into the plurality of mounting ports 116. The wafer 104 of the film frame carrier 102 may be at least partially supported by the plurality of seal plugs 134 on the planar surface 111 of the chuck 110. Accordingly, the wafer 104 of the film frame carrier 102 may be held in position by the chuck 110 when one or more fabrication or inspection processes are performed on the wafer 104. The contact between the plurality of seal plugs 134 and the wafer 104 of the film frame carrier 102 may reduce a “memory” effect of permanent deformation of the wafer 104 under the negative pressure applied by the vacuum source 140 over the plurality of mounting ports 116 and the atmospheric pressure of the reservoir 133.

The system 100 may further comprise a plurality of set screws 136 disposed in the access port 135 of each of the plurality of seal plugs 134, as shown in FIG. 4B. The plurality of set screws 136 may extend through the reservoir 133 to abut each orifice screw 137. The plurality of seal plugs 134 may be supported by the plurality of set screws 136 to remain flush with the planar surface 111 of the chuck 110. Accordingly, when an inspection process is performed on the wafer 104, portions of the wafer 104 over the plurality of mounting ports 116 may be kept in the focus plane, as sagging into the mounting ports 116 would move the portions of the wafer 104 out of the focus plane and distort imaging. The plurality of set screws 136 may further prevent dies of the wafer 104 from falling through the access port 135.

The system 100 may further comprise an actuator 150 disposed beneath the chuck 110, as shown in FIG. 1A. The actuator 150 may be configured to simultaneously lift the plurality of lift pins 120 to extend out of the plurality of apertures 113 above the planar surface 111 of the chuck 110. The actuator 150 may be further configured to simultaneously lower the plurality of lift pins 120 to retract into the plurality of apertures 113 beneath the planar surface 111 of the chuck 110. Accordingly, the actuator 150 may allow the chuck 110 to accommodate support of both the whole wafer 101 and the film frame carrier 102 by movement of the plurality of lift pins 120.

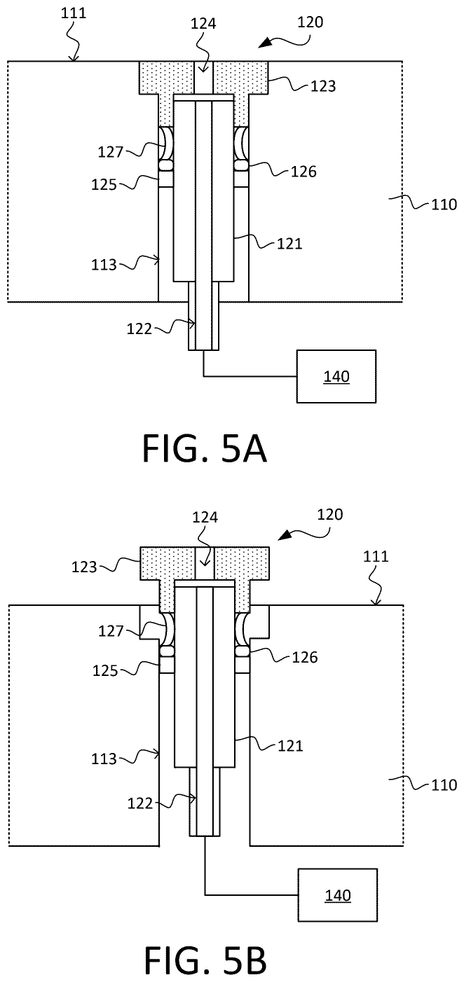

In some embodiments, the plurality of lift pins 120 may each comprise a pin body 121 having an axial bore 122, as shown in FIG. 5A and FIG. 5B. The pin body 121 may be configured to axially move within one of the plurality of apertures 113. For example, the actuator 150 may be connected to each pin body 121 to axially move each pin body 121 within the plurality of apertures 113 from a retracted position (shown in FIG. 5A) to an extended position (shown in FIG. 5B), or any position therebetween. The vacuum source 140 may be in fluid communication with the axial bore 122, such that the vacuum source 140 is configured to apply the negative pressure to the wafer 104 of the film frame carrier 102 supported on the planar surface 111 of the chuck 110 through the axial bore 122. In other words, when the plurality of lift pins 120 are retracted beneath the planar surface 111 of the chuck 110 and the wafer 104 of the film frame carrier 102 is disposed on the planar surface 111 of the chuck 110, the vacuum source 140 can apply the negative pressure to the wafer 104 through both the plurality of vacuum ports (i.e., the ports of the central hub 114 and the plurality of micro ports 115) and the plurality of apertures 113 that house the plurality of lift pins 120. Accordingly, the area of the wafer 104 applied with the negative pressure may increase, and thereby further hold the wafer 104 of the film frame carrier 102 in position by the chuck 110 when one or more fabrication or inspection processes are performed on the wafer 104.

In some embodiments, the plurality of lift pins 120 may each further comprise a pin cap 123 disposed on the pin body 121. The pin cap 123 may be made of an elastomeric material press fit onto the pin body 121. The whole wafer 101 may be at least partially supported by each pin cap 123 above the planar surface 111 of the chuck 110 when the plurality of lift pins 120 are extended out of the plurality of apertures 113 above the planar surface 111 of the chuck 110. In addition, the wafer 104 of the film frame carrier 102 may be at least partially supported by the pin cap 123 on the planar surface 111 of the chuck 110 when the plurality of lift pins 120 are retracted into the plurality of apertures 113 beneath the planar surface 111 of the chuck 110, with the pin cap 123 being flush with the planar surface 111 of the chuck 110. Each pin cap 123 may define a pin hole 124 that is coaxial with the axial bore 122 of the pin body 121. The pin hole 124 may be in fluid communication with the vacuum source 140. Accordingly, the wafer 104 of the film frame carrier 102 may be held in position by the chuck 110 when one or more fabrication or inspection processes are performed on the wafer 104. The contact between each pin cap 123 and the wafer 104 of the film frame carrier 102 may reduce a “memory” effect of permanent deformation on the wafer 104 under the negative pressure applied by the vacuum source 140 through the pin hole 124.

In some embodiments, the plurality of lift pins 120 may each further comprise a pin shoulder 125 circumferentially defined around the pin body 121. A sealing member 126 may be provided on the pin shoulder 125 to seal each pin body 121 in the plurality of apertures 113 and draw the negative pressure from the pin hole 124.

In some embodiments, the pin cap 123 may be movable relative to the pin body 121. For example, the plurality of lift pins 120 may further comprise a wave spring 127 configured to suspend the pin cap 123 on the pin body 121 as the whole wafer 101 is supported by the plurality of lift pins 120 above the planar surface 111 of the chuck 110. The wave spring 127 may be disposed between the pin cap 123 and the pin shoulder 125 so as to move with the pin body 121 as each pin body 121 axially moves within the plurality of apertures 113.

In some embodiments, the chuck 110 may be disposed on a base member 131, with a shim 132 provided therebetween, as shown in FIG. 1A. A thickness of the shim 132 may define a relative height of the planar surface 111 of the chuck 110, which may be independent of the axial distance moved by the plurality of lift pins 120. For example, a shim 132 with a smaller thickness may cause the plurality of lift pins 120 to extend out of the plurality of apertures 113 above the planar surface 111 of the chuck 110 by a relative distance that may be greater than that of a shim 132 with a larger thickness.

The system 100 may further comprise a processor 160. The processor 160 may include a microprocessor, a microcontroller, or other devices. The processor 160 may be coupled to the components of the system 100 in any suitable manner (e.g., via one or more transmission media, which may include wired and/or wireless transmission media) such that the processor 160 can receive output. The processor 160 may be configured to perform a number of functions using the output. An inspection tool can receive instructions or other information from the processor 160. The processor 160 optionally may be in electronic communication with another inspection tool, a metrology tool, a repair tool, or a review tool (not illustrated) to receive additional information or send instructions.

The processor 160 may be part of various systems, including a personal computer system, image computer, mainframe computer system, workstation, network appliance, internet appliance, or other device. The subsystem(s) or system(s) may also include any suitable processor known in the art, such as a parallel processor. In addition, the subsystem(s) or system(s) may include a platform with high-speed processing and software, either as a standalone or a networked tool.

The processor 160 may be disposed in or otherwise part of the system 100 or another device. In an example, the processor 160 may be part of a standalone control unit or in a centralized quality control unit. Multiple processors 160 may be used, defining multiple subsystems of the system 100.

The processor 160 may be implemented in practice by any combination of hardware, software, and firmware. Also, its functions as described herein may be performed by one unit, or divided up among different components, each of which may be implemented in turn by any combination of hardware, software and firmware. Program code or instructions for the processor 160 to implement various methods and functions may be stored in readable storage media, such as a memory.

If the system 100 includes more than one subsystem, then the different processors 160 may be coupled to each other such that images, data, information, instructions, etc. can be sent between the subsystems. For example, one subsystem may be coupled to additional subsystem(s) by any suitable transmission media, which may include any suitable wired and/or wireless transmission media known in the art. Two or more of such subsystems may also be effectively coupled by a shared computer-readable storage medium (not shown).

The processor 160 may be configured to perform a number of functions using the output of the system 100 or other output. For instance, the processor 160 may be configured to send the output to an electronic data storage unit or another storage medium. The processor 160 may be further configured as described herein.

The processor 160 may be configured according to any of the embodiments described herein. The processor 160 also may be configured to perform other functions or additional steps using the output of the system 100 or using images or data from other sources.

The processor 160 may be communicatively coupled to any of the various components or sub-systems of system 100 in any manner known in the art. Moreover, the processor 160 may be configured to receive and/or acquire data or information from other systems (e.g., inspection results from an inspection system such as a review tool, a remote database including design data and the like) by a transmission medium that may include wired and/or wireless portions. In this manner, the transmission medium may serve as a data link between the processor 160 and other subsystems of the system 100 or systems external to system 100. Various steps, functions, and/or operations of system 100 and the methods disclosed herein are carried out by one or more of the following: electronic circuits, logic gates, multiplexers, programmable logic devices, ASICs, analog or digital controls/switches, microcontrollers, or computing systems. Program instructions implementing methods such as those described herein may be transmitted over or stored on carrier medium. The carrier medium may include a storage medium such as a read-only memory, a random-access memory, a magnetic or optical disk, a non-volatile memory, a solid-state memory, a magnetic tape, and the like. A carrier medium may include a transmission medium such as a wire, cable, or wireless transmission link. For instance, the various steps described throughout the present disclosure may be carried out by a single processor 160 (or computer subsystem) or, alternatively, multiple processors 160 (or multiple computer subsystems). Moreover, different sub-systems of the system 100 may include one or more computing or logic systems. Therefore, the above description should not be interpreted as a limitation on the present disclosure but merely an illustration.

The processor 160 may be in electronic communication with the vacuum source 140. For example, the processor 160 configured to control the vacuum source 140 to apply the negative pressure to the wafer 104 of the film frame carrier 102 supported on the planar surface 111 of the chuck 110 through the plurality of vacuum ports.

The processor 160 may be in electronic communication with the actuator 150. For example, the processor 160 may be further configured to control the actuator 150 to lift the plurality of lift pins 120 to extend out of the plurality of apertures 113 above the planar surface 111 of the chuck 110. The processor 160 may be further configured to control the actuator 150 to lower the plurality of lift pins 120 to retract into the plurality of apertures 113 beneath the planar surface 111 of the chuck 110.

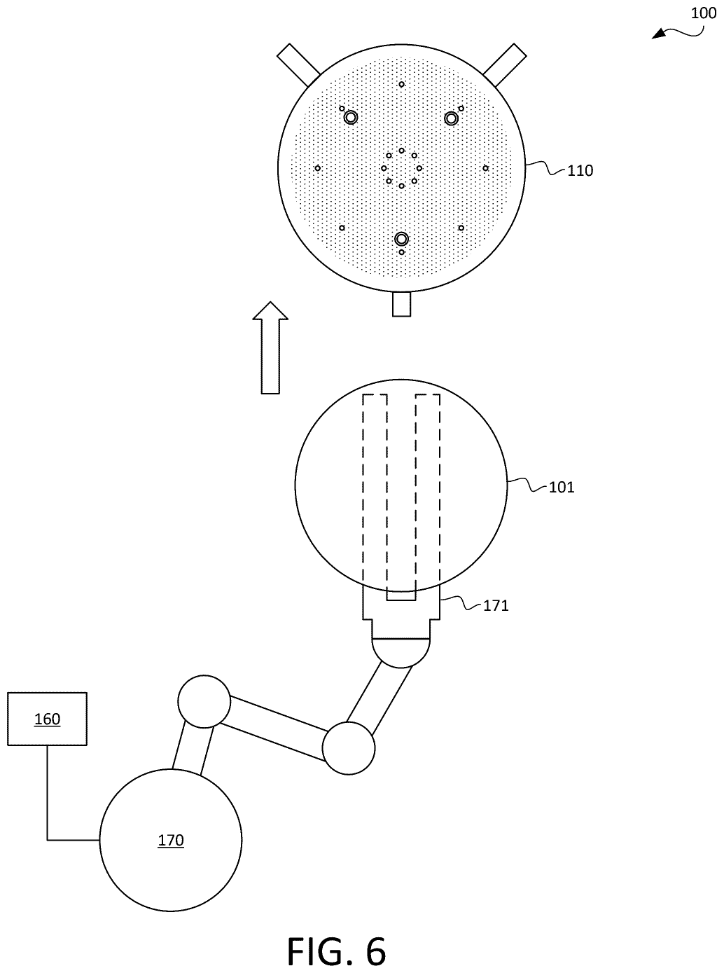

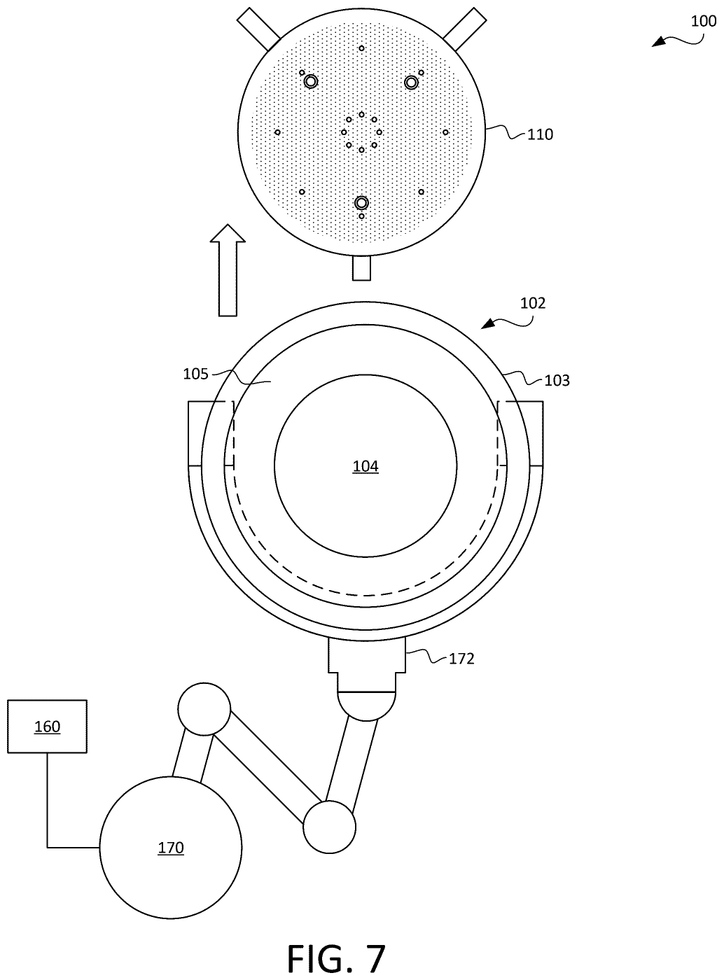

The system 100 may further comprise a robot arm 170, a first end effector 171, and a second end effector 172, as shown in FIG. 6 and FIG. 7. The first end effector 171 may be configured to support the whole wafer 101 and removably dispose the whole wafer 101 onto the plurality of lift pins 120 extended out of the plurality of apertures 113 above the planar surface 111 of the chuck 110. The second end effector 172 configured to support the film frame carrier 102 and removably dispose the frame 103 of the film frame carrier 102 onto the plurality of frame handles 130 and the wafer 104 of the film frame carrier 102 onto the planar surface 111 of the chuck 110. In some embodiments, the robot arm 170 may be configured to removably engage each of the first end effector 171 and the second end effector 172. Alternatively, a separate robot arm 170 may be engaged with each of the first end effector 171 and the second end effector 172.

The processor 160 may be in electronic communication with the robot arm 170 to control the robot arm 170 to move the first end effector 171 and/or the second end effector 172 to removably dispose the whole wafer 101 and the film frame carrier 102 on the chuck 110. The robot arm 170 may be configured to move the first end effector 171 and the second end effector 172 by actuating one or more joints of the robot arm 170 to position the first end effector 171 and the second end effector 172 within a volume defined by the envelope of the robot arm 170. The chuck 110 may be provided within the volume. The size and shape of the envelope of the robot arm 170 may depend on the arrangement of the robot arm 170 and its degrees of freedom. Although the robot arm 170 is shown as a polar robot in FIG. 6 and FIG. 7, it should be understood that the robot arm 170 may also include cartesian and cylindrical manipulators or the like and is not limited herein. The robot arm 170 may be configured to move the first end effector 171 and the second end effector 172 in three translational directions within the volume (i.e., x, y, and z directions). For example, the robot arm 170 may be configured to move the first end effector 171 in a direction normal to the planar surface 111 of the chuck 110 to dispose the whole wafer 101 onto the plurality of lift pins 120 extended out of the plurality of apertures 113 above the planar surface 111 of the chuck 110, and the robot arm 170 may be further configured to move the second end effector 172 in a direction normal to the planar surface 111 of the chuck 110 to dispose the frame 103 of the film frame carrier 102 onto the plurality of frame handles 130 and the wafer 104 of the film frame carrier 102 onto the planar surface 111 of the chuck 110. After the first end effector 171 releases the whole wafer 101, the robot arm 170 may be configured to move the first end effector 171 away from the chuck 110 in a direction parallel to the planar surface 111 of the chuck 110 to dispose the whole wafer 101 on the chuck 110. Similarly, after the second end effector 172 releases the film frame carrier 102, the robot arm 170 may be configured to move the first end effector 171 away from the chuck 110 in a direction parallel to the planar surface 111 of the chuck 110 to dispose the film frame carrier 102 on the chuck 110.

To remove the whole wafer 101 from the chuck 110, the robot arm 170 may be configured to move the first end effector 171 in the direction parallel to the planar surface 111 of the chuck 110 between the planar surface 111 and the whole wafer 101, engage the whole wafer 101 with the first end effector 171, and then move the first end effector 171 away from the chuck 110 in the direction normal to the planar surface 111 of the chuck 110 to remove the whole wafer 101 from the plurality of lift pins 120. Similarly, to remove the film frame carrier 102 from the chuck 110, the robot arm 170 may be configured to move the second end effector 172 in the direction parallel to the planar surface 111 of the chuck 110 beneath the frame 103 of the film frame carrier 102, engage the frame 103 of the film frame carrier 102 with the second end effector 172, and then move the second end effector 172 away from the chuck 110 in the direction normal to the planar surface 111 of the chuck 110 to remove the frame 103 of the film frame carrier 102 from the plurality of frame handles 130.

With the system 100, the chuck 110 can hold both a whole wafer 101 and a film frame carrier 102, so that one or more fabrication or inspection processes can be performed on the whole wafer 101 or the wafer 104 of the film frame carrier 102. In particular, by moving the plurality of lift pins 120 above the planar surface 111 of the chuck 110, the whole wafer 101 can be disposed on the plurality of lift pins 120, and by moving the plurality of lift pins 120 beneath the planar surface 111 of the chuck 110, the wafer 104 of the film frame carrier 102 can be disposed on the planar surface 111 of the chuck 110, while the frame 103 of the film frame carrier 102 is disposed on the plurality of frame handles 130. In addition, simply exchanging the first end effector 171 with the second end effector 172 can allow the robot arm 170 to handle both the whole wafer 101 and the film frame carrier 102 with the same chuck 110, which reduces tool downtime, increases throughput, and reduces hardware costs.

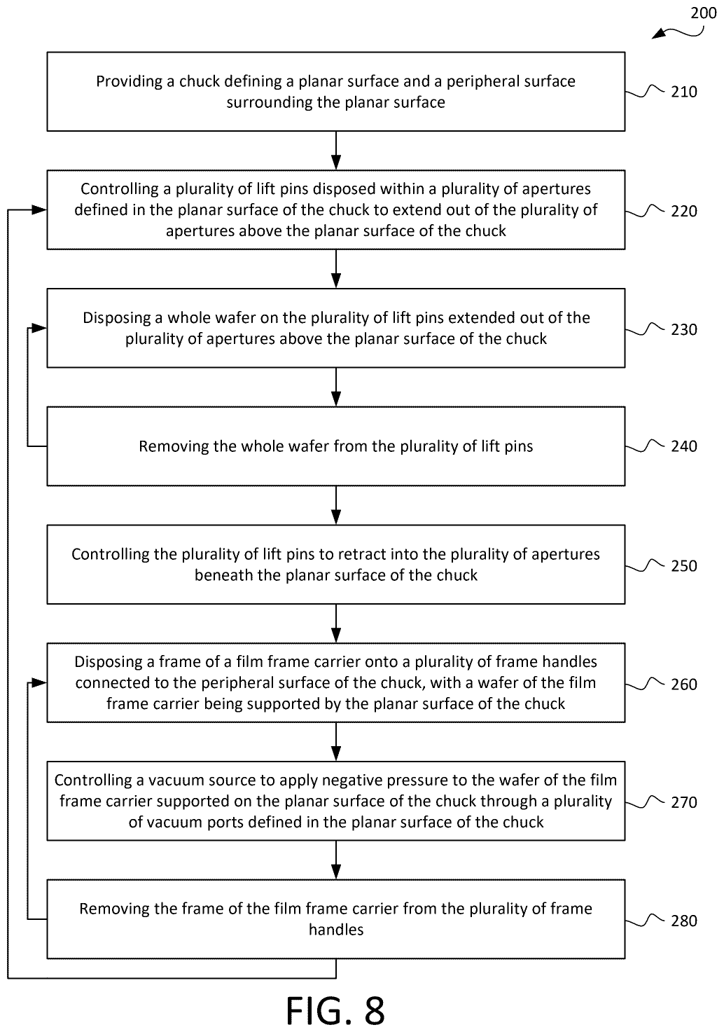

Another embodiment of the present disclosure provides a method 200. As shown in FIG. 8, the method 200 may comprise the following steps.

At step 210, a chuck is provided, the chuck defining a planar surface and a peripheral surface surrounding the planar surface. In some embodiments, the chuck may be cylindrical, with the planar surface being a circular top surface of the chuck and the peripheral surface being an annular side surface of the chuck. The diameter of the planar surface of the chuck may be greater than or equal to the diameter of the whole wafer or the wafer of the film frame carrier. For example, a diameter of the planar surface of the chuck that is greater than 300 mm may be configured to support a whole wafer and a wafer of a film frame carrier that is 300 mm or less (i.e., both 300 mm wafers and 200 mm wafers).

At step 220, a plurality of lift pins disposed within a plurality of apertured defined in the planar surface of the chuck are controlled to extend out of the plurality of apertures above the planar surface of the chuck. The plurality of apertures may be circumferentially arranged on the planar surface of the chuck in a regular arrangement or symmetrical pattern. The radial position of each of the plurality of apertures relative to a center point of the planar surface of the chuck may be provided such that each of the plurality of apertures may be covered by the whole wafer. An actuator may be configured to control the movement of the plurality of lift pins to extend out of the plurality of apertures.

At step 230, a whole wafer is disposed on the plurality of lift pins extended out of the plurality of apertures above the planar surfaces of the chuck. With the whole wafer disposed on the chuck, one or more fabrication or inspection processes can be performed on the whole wafer.

At step 240, the whole wafer is removed the plurality of lift pins.

After removing the whole wafer from the chuck, another whole wafer can be disposed on the chuck. Accordingly, steps 230 and 240 can be repeated any number of times in order to perform one or more fabrication or inspection processes on any number of whole wafers. Alternatively, the method can proceed as follows.

At step 250, the plurality of lift pins are controlled to retract into the plurality of apertures beneath the planar surface of the chuck.

At step 260, a frame of a film frame carrier is disposed onto a plurality of frame handles connected to the peripheral surface of the chuck, with a wafer of the film frame carrier being supported by the planar surface of the chuck. With the film frame carrier disposed on the chuck, one or more fabrication or inspection processes can be performed on the wafer of the film frame carrier. For example, the plurality of frame handles may be arranged at regular intervals around the circumference of the chuck or at symmetrical positions relative to the chuck.

At step 270, a vacuum source is controlled to apply negative pressure to the wafer of the film frame carrier supported on the planar surface of the chuck through a plurality of vacuum ports defined in the planar surface of the chuck. The plurality of vacuum ports may be arranged on the planar surface of the chuck in a regular arrangement or a symmetrical pattern. The radial position of each of the plurality of vacuum ports relative to the center point of the planar surface of the chuck may be provided such that at least some of the plurality of vacuum ports may be covered by the wafer of the film frame carrier. The wafer of the film frame carrier may be held in position by the negative pressure applied to the chuck for one or more fabrication or inspection processes to be performed on the wafer.

At step 280, the frame of the film frame carrier is removed from the plurality of frame handles. In some embodiments, the vacuum source may stop applying negative pressure once the film frame carrier is removed from the chuck. Alternatively, the vacuum source may continue to apply negative pressure.

After removing the film frame carrier from the chuck, another film frame carrier can be disposed on the chuck. Accordingly, steps 260-280 can be repeated any number of times in order to perform one or more fabrication or inspection processes on any number of whole wafers. Alternatively, after removing the film frame carrier from the chuck, steps 220 and 230 can be repeated to dispose a whole wafer on the chuck, and steps 230 and 240 can be repeated any number of times in order to perform one or more fabrication or inspection processes on any number of whole wafers. Accordingly, the sequence of steps of the method 200 may be adaptable for the handling of both whole wafers and film frame carriers.

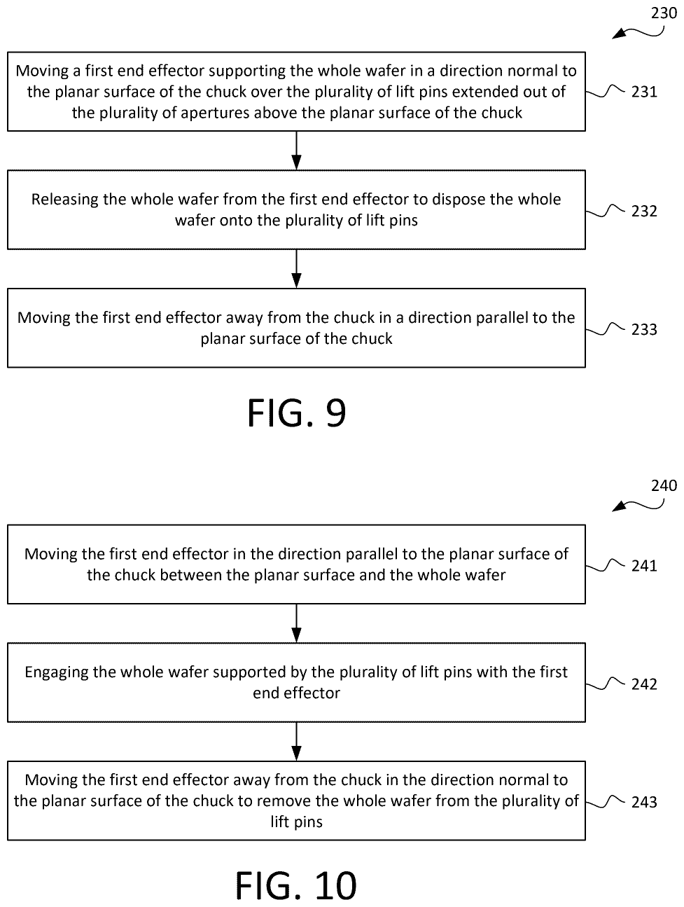

In some embodiments, step 230 may comprise the following steps shown in FIG. 9.

At step 231, a first end effector supporting the whole wafer is moved in a direction normal to the planar surface of the chuck over the plurality of lift pins extended out of the plurality of apertures above the planar surface of the chuck.

At step 232, the whole wafer is released from the first end effector to dispose the whole wafer onto the plurality of lift pins.

At step 233, the first end effector is moved away from the chuck in a direction parallel to the planar surface of the chuck.

In some embodiments, step 240 may comprise the following steps shown in FIG. 10.

At step 241, the first end effector is moved in the direction parallel to the planar surface of the chuck between the planar surface and the whole wafer.

At step 242, the whole wafer supported by the plurality of lift pins is engaged with the first end effector.

At step 243, the first end effector is moved away from the chuck in the direction normal to the planar surface of the chuck to remove the whole wafer from the plurality of lift pins.

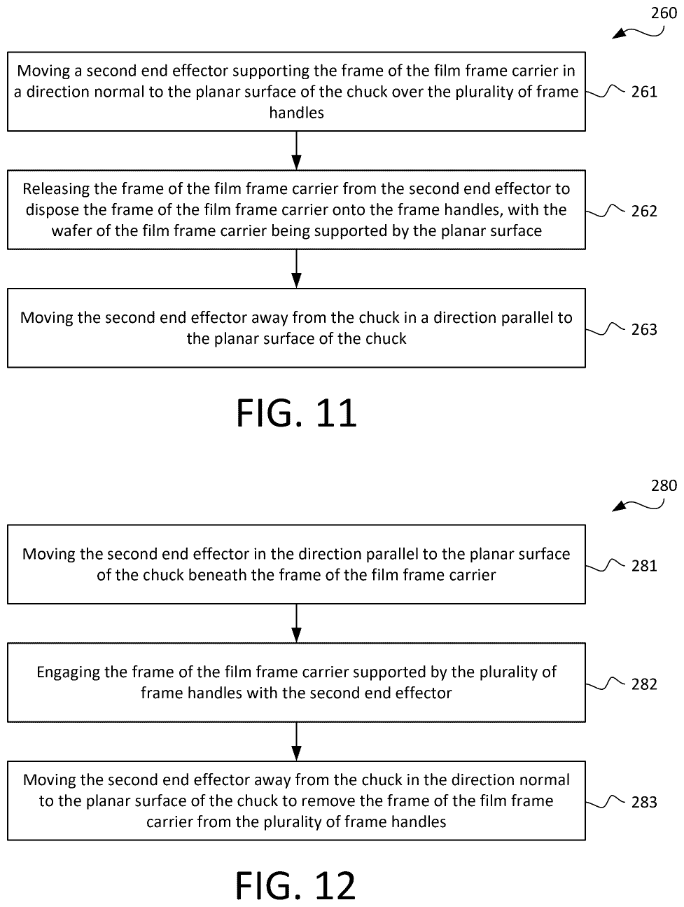

In some embodiments, step 260 may comprise the following steps shown in FIG. 11.

At step 261, a second end effector supporting the frame of the film frame carrier is moved in a direction normal to the planar surface of the chuck over the plurality of frame handles.

At step 262, the frame of the film frame carrier is released from the second end effector to dispose the frame of the film frame carrier onto the frame handles, with the wafer of the film frame carrier being supported by the planar surface of the chuck.

At step 263, the second end effector is moved away from the chuck in a direction parallel to the planar surface of the chuck.

In some embodiments, step 280 may comprise the following steps shown in FIG. 12.

At step 281, the second end effector is moved in the direction parallel to the planar surface of the chuck beneath the frame of the film frame carrier.

At step 282, the frame of the film frame carrier supported by the plurality of frame handles is engaged with the second end effector.

At step 283, the second end effector is moved away from the chuck in the direction normal to the planar surface of the chuck to remove the frame of the film frame carrier from the plurality of frame handles.

In some embodiments, a robot arm may be configured to engage the first end effector and the second end effector in an exchangeable manner.

With the method 200, the chuck can hold both a whole wafer and a film frame carrier, so that one or more fabrication or inspection processes can be performed on the whole wafer or the wafer of the film frame carrier. In particular, by moving the plurality of lift pins above the planar surface of the chuck, the whole wafer can be disposed on the plurality of lift pins, and by moving the plurality of lift pins beneath the planar surface of the chuck, the wafer of the film frame carrier can be disposed on the planar surface of the chuck, while the frame of the film frame carrier is disposed on the plurality of frame handles. In addition, simply exchanging the first end effector with the second end effector can allow the robot arm to handle both the whole wafer and the film frame carrier with the same chuck, which reduces tool downtime, increases throughput, and reduces hardware costs.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. A system comprising:
a chuck defining a planar surface and peripheral surface surrounding the planar surface;
a plurality of lift pins disposed within a plurality of apertures defined in the planar surface of the chuck, the plurality of lift pins being configured to extend out of the plurality of apertures above the planar surface to support a whole wafer; and
a plurality of frame handles connected to the peripheral surface of the chuck, the plurality of frame handles being configured to support a frame of a film frame carrier;
wherein the plurality of lift pins are further configured to retract into the plurality of apertures beneath the planar surface, with the planar surface of the chuck being configured to support a wafer of the film frame carrier.

2. The system of claim 1, wherein a plurality of mounting ports are further defined in the planar surface, and the system further comprises:
a plurality of orifice screws disposed in each of the plurality of mounting ports, the plurality of orifice screws being configured to secure the chuck to a base member disposed beneath the chuck; and
a plurality of seal plugs disposed in the plurality of mounting ports and flush with the planar surface;
wherein the wafer of the film frame carrier is at least partially supported by the plurality of seal plugs on the planar surface of the chuck.

3. The system of claim 2, wherein each seal plug includes an access port that is coaxial with an axial bore of each orifice screw, and the system further comprises:
a plurality of set screws disposed in the access port of each of the plurality of seal plugs and extending to abut each orifice screw, wherein the plurality of set screws are configured to support the plurality of seal plugs to remain flush with the planar surface of the chuck.

4. The system of claim 1, further comprising:
a vacuum source;
wherein a plurality of vacuum ports are further defined in the planar surface, the vacuum source being in fluid communication with the plurality of vacuum ports, and the vacuum source being configured to apply negative pressure to the wafer of the film frame carrier supported on the planar surface of the chuck through the plurality of vacuum ports.

5. The system of claim 4, wherein the plurality of vacuum ports include a central hub defined by ports provided in a circular arrangement around a center point of the chuck and a plurality of micro ports distributed across the planar surface of the chuck surrounding the central hub.

6. The system of claim 4, wherein the plurality of lift pins each comprise:
a pin body having an axial bore, the pin body being configured to axially move within one of the plurality of apertures;
wherein the vacuum source is in fluid communication with the axial bore, and the vacuum source being configured to apply the negative pressure to the wafer supported on the planar surface of the chuck through the axial bore.

7. The system of claim 6, wherein the plurality of lift pins each further comprise:
a pin cap disposed on the pin body, the pin cap defining a pin hole coaxial with the axial bore and in fluid communication with the vacuum source;
wherein the wafer of the film frame carrier is at least partially supported by the pin cap on the planar surface of the chuck.

8. The system of claim 7, wherein the plurality of lift pins each further comprise:
a wave spring configured to suspend the pin cap on the pin body as the whole wafer is supported by the plurality of lift pins above the planar surface of the chuck.

9. The system of claim 4, further comprising:
a processor configured to control the vacuum source to apply the negative pressure to the wafer of the film frame carrier supported on the planar surface of the chuck through the plurality of vacuum ports.

10. The system of claim 1, further comprising:
an actuator disposed beneath the chuck, the actuator being configured to simultaneously lift the plurality of lift pins to extend out of the plurality of apertures above the planar surface of the chuck, and the actuator being further configured to simultaneously lower the plurality of lift pins to retract into the plurality of apertures beneath the planar surface of the chuck.

11. The system of claim 10, further comprising:
a processor configured to control the actuator to lift the plurality of lift pins to extend out of the plurality of apertures above the planar surface of the chuck and lower the plurality of lift pins to retract into the plurality of apertures beneath the planar surface of the chuck.

12. The system of claim 1, further comprising:
a first end effector configured to support the whole wafer and removably dispose the whole wafer onto the plurality of lift pins extended out of the plurality of apertures above the planar surface of the chuck; and
a second end effector configured to support the film frame carrier and removably dispose the frame of the film frame carrier onto the plurality of frame handles and the wafer of the film frame carrier onto the planar surface of the chuck.

13. The system of claim 12, further comprising:
a robot arm configured to engage the first end effector and move the first end effector to removably dispose the whole wafer onto the plurality of lift pins extended out of the plurality of apertures above the planar surface of the chuck.

14. The system of claim 13, wherein the robot arm is further configured to engage the second end effector and move the second end effector to removably dispose the frame of the film frame carrier onto the plurality of frame handles and the wafer of the film frame carrier onto the planar surface of the chuck.

15. A method comprising:
providing a chuck defining a planar surface and peripheral surface surrounding the planar surface;
controlling a plurality of lift pins disposed within a plurality of apertures defined in the planar surface of the chuck to extend out of the plurality of apertures above the planar surface of the chuck;
disposing a whole wafer on the plurality of lift pins extended out of the plurality of apertures above the planar surface of the chuck;
removing the whole wafer from the plurality of lift pins;
controlling the plurality of lift pins to retract into the plurality of apertures beneath the planar surface of the chuck;
disposing a frame of a film frame carrier onto a plurality of frame handles connected to the peripheral surface of the chuck, with a wafer of the film frame carrier being supported by the planar surface of the chuck; and
removing the frame of the film frame carrier from the plurality of frame handles.

16. The method of claim 15, further comprising:
controlling a vacuum source to apply negative pressure to the wafer of the film frame carrier supported on the planar surface of the chuck through a plurality of vacuum ports defined in the planar surface of the chuck.

17. The method of claim 15, wherein disposing the whole wafer on the plurality of lift pins extended out of the plurality of apertures above the planar surface of the chuck comprises:
moving a first end effector supporting the whole wafer in a direction normal to the planar surface of the chuck over the plurality of lift pins extended out of the plurality of apertures above the planar surface of the chuck;
releasing the whole wafer from the first end effector to dispose the whole wafer onto the plurality of lift pins; and
moving the first end effector away from the chuck in a direction parallel to the planar surface of the chuck.

18. The method of claim 17, wherein removing the whole wafer from the plurality of lift pins comprises:
moving the first end effector in the direction parallel to the planar surface of the chuck between the planar surface and the whole wafer;
engaging the whole wafer supported by the plurality of lift pins with the first end effector; and
moving the first end effector away from the chuck in the direction normal to the planar surface of the chuck to remove the whole wafer from the plurality of lift pins.

19. The method of claim 15, wherein disposing the frame of the film frame carrier onto the plurality of frame handles comprises:
moving a second end effector supporting the frame of the film frame carrier in a direction normal to the planar surface of the chuck over the plurality of frame handles;
releasing the frame of the film frame carrier from the second end effector to dispose the frame of the film frame carrier onto the plurality of frame handles, with the wafer of the film frame carrier being supported by the planar surface of the chuck; and
moving the second end effector away from the chuck in a direction parallel to the planar surface of the chuck.

20. The method of claim 19, wherein removing the frame of the film frame carrier from the plurality of frame handles comprises:
moving the second end effector in the direction parallel to the planar surface of the chuck beneath the frame of the film frame carrier;
engaging the frame of the film frame carrier supported by the plurality of frame handles with the second end effector; and
moving the second end effector away from the chuck in the direction normal to the planar surface of the chuck to remove the frame of the film frame carrier from the plurality of frame handles.
